(19) United States
(12) Patent Application Publication
(10) Pub. No.: US 2026/0181816 A1
(43) Pub. Date: Jun. 25, 2026

(54) INTERRUPTION DEVICE

(71) Applicant: Panasonic Intellectual Property Management Co., Ltd., Osaka (JP)

(72) Inventors: MASATO NAKAMURA, Hyogo (JP); SHUN ITO, Hyogo (JP); SHINYA KIMOTO, Osaka (JP)

(21) Appl. No.: 19/128,584

(22) PCT Filed: Dec. 20, 2023
(86) PCT No.: PCT/JP2023/045594

§ 371 Date: May 9, 2025

(30) Foreign Application Priority Data
Dec. 23, 2022 (JP) 2022-206525

(51) Int. Cl. H05K 7/20

(52) U.S. Cl. CPC H05K 7/20145

(57) ABSTRACT

A breaker device includes: a casing (for example, an upper casing and a lower casing; an igniter disposed in the casing; a conductor including a separating portion disposed below the igniter; a pusher disposed at a first position between the separating portion and the igniter and configured to cut off the separating portion and move from the first position to a second position located below the first position; and a coolant disposed at a level below the pusher and including a recessed portion or a through-hole.

### TECHNICAL FIELD

The present disclosure relates to breaker devices.

### BACKGROUND ART

There are conventionally known breaker devices that, when in use, are connected to an electrical circuit. Such a breaker device includes: a casing; and a pusher that is disposed in the casing and moves from a first position to a second position by gas generated by an igniter when turned ON, and the pusher moving from the first position to the second position cuts a conductor, thus interrupting an electrical path. An electric arc may be generated when the conductor is cut and therefore, Patent Literature (PTL) 1 discloses a breaker device including, inside a casing, a coolant for extinguishing electric arcs (refer to PTL 1).

### CITATION LIST

### Patent Literature

PTL 1: Unexamined Japanese Patent Publication No. 2021-61147

### SUMMARY OF INVENTION

### Technical Problem

From the perspective of improving the arc-extinguishing performance, for example, it is desired that the cooling performance in a breaker device be improved.

A breaker device according to one aspect of the present disclosure includes: a casing; an igniter disposed in the casing; a conductor including a separating portion disposed below the igniter; a pusher disposed at a first position between the separating portion and the igniter and configured to cut off the separating portion and move from the first position to a second position located below the first position; and a coolant disposed at a level below the pusher and including a recessed portion or a through-hole.

A breaker device according to one aspect of the present disclosure includes: a casing; an igniter disposed in the casing; a conductor including a separating portion disposed below the igniter; a pusher disposed at a first position between the separating portion and the igniter and configured to cut off the separating portion and move from the first position to a second position located below the first position; and a coolant disposed at a level below the pusher. The coolant includes a plurality of layers stacked on top of each other. An end surface of each of the plurality of layers is disposed facing a lower surface of the pusher.

According to one aspect of the present disclosure, it is possible to realize a breaker device in which the cooling performance can be improved as compared to a conventional technique.

### BRIEF DESCRIPTION OF DRAWINGS

FIG. 1 is a perspective view illustrating a breaker device according to Embodiment 1.

FIG. 2 is a cross-sectional view of a breaker device according to Embodiment 1 cut along the YZ plane.

FIG. 3 is a cross-sectional view of a breaker device according to Embodiment 1 cut along the XZ plane.

FIG. 4 is a perspective view illustrating a coolant according to Embodiment 1.

FIG. 5 is a flowchart illustrating a manufacturing process of a breaker device according to Embodiment 1.

FIG. 6 is a perspective view illustrating a coolant according to Variation 1 of Embodiment 1.

FIG. 7 is a perspective view illustrating a coolant according to Variation 2 of Embodiment 1.

FIG. 8 is a perspective view illustrating a coolant according to Variation 3 of Embodiment 1.

FIG. 9 is a perspective view illustrating a coolant according to Variation 4 of Embodiment 1.

FIG. 10 is a cross-sectional view of a breaker device according to Embodiment 2 cut along the XZ plane.

FIG. 11A is a perspective view illustrating another example of a coolant.

FIG. 11B is a perspective view illustrating another example of a coolant.

FIG. 11C is a perspective view illustrating another example of a coolant.

### DESCRIPTION OF EMBODIMENTS

A breaker device according to one aspect of the present disclosure includes: a casing; an igniter disposed in the casing; a conductor including a separating portion disposed below the igniter; a pusher disposed at a first position between the separating portion and the igniter and configured to cut off the separating portion and move from the first position to a second position located below the first position; and a coolant disposed at a level below the pusher and including a recessed portion or a through-hole.

Thus, the area of contact between the coolant and an electric arc or gas generated upon ignition can be increased as compared to when the coolant does not include a recessed portion or a through-hole. The increase in said area promotes the heat exchange between the coolant and the electric arc or the gas, leading to an increased likelihood that the heat of the electric arc or the gas will be absorbed. Thus, with the breaker device, it is possible to improve the cooling performance as compared to a conventional technique.

Furthermore, for example, the recessed portion or the through-hole may be one of a plurality of recesses or a plurality of through-holes in the coolant.

Thus, since there is more than one recessed portion or through-hole, it is possible to further improve the cooling performance with the breaker device.

Furthermore, for example, it is preferable that the separating portion include a hole extending through the separating portion, and the recessed portion or the through-hole in the coolant overlap the hole of the separating portion as viewed from above.

As a result, gas generated upon ignition easily flows from the hole of the separating portion to the recessed portion or the through-hole and therefore, it is possible to promote the heat exchange in the recessed portion or the through-hole. Thus, with the breaker device, it is possible to increase the cooling efficiency in the recessed portion or the through-hole.

Furthermore, for example, it is preferable that the coolant include the recessed portion, and the recessed portion be open upward and face a lower surface of the pusher.

As a result, upon ignition, gas that flows from the first position to the second position is likely to flow into the recessed portion and therefore, it is possible to promote the heat exchange in the recessed portion. Thus, with the breaker device, it is possible to increase the cooling efficiency in the recessed portion.

Furthermore, for example, it is preferable that the coolant include the through-hole, and the through-hole extend through the coolant from an upper surface of the coolant to a lower surface of the coolant.

As a result, upon ignition, gas that flows from the first position to the second position is likely to flow into the through-hole and therefore, it is possible to promote the heat exchange in the through-hole. Thus, with the breaker device, it is possible to further improve the cooling performance in the through-hole.

Furthermore, for example, it is preferable that the coolant be located at a level below the separating portion, and a width of an opening of the recessed portion or a width of an opening of the through-hole be greater than a width of the separating portion.

As a result, upon ignition, the opening of the recessed portion or the opening of the through-hole can be kept from being blocked by the separating portion and therefore, it is possible to more reliably perform the heat exchange in the recessed portion or the through-hole.

Furthermore, for example, it is preferable that the coolant include a plurality of layers stacked on top of each other, and an end surface of each of the plurality of layers be disposed facing a lower surface of the pusher.

As a result, upon ignition, gas that flows from the first position to the second position is likely to flow into each interface between the plurality of layers and therefore, with the breaker device, it is possible to further improve the cooling performance as compared to a conventional technique.

Furthermore, for example, the recessed portion may be provided in a side surface of the coolant, or the through-hole may extend through the side surface of the coolant.

As a result, upon ignition, gas that flows in from the side surface of the coolant can be effectively cooled.

Furthermore, a breaker device according to one aspect of the present disclosure includes: a casing; an igniter disposed in the casing; a conductor including a separating portion disposed below the igniter; a pusher disposed at a first position between the separating portion and the igniter and configured to cut off the separating portion and move from the first position to a second position located below the first position; and a coolant disposed at a level below the pusher. The coolant includes a plurality of layers stacked on top of each other. An end surface of each of the plurality of layers is disposed facing a lower surface of the pusher.

As a result, upon ignition, gas that flows from the first position to the second position is likely to flow into each interface between the plurality of layers and therefore, with the breaker device, it is possible to improve the cooling performance as compared to a conventional technique. For example, with the breaker device, the cooling performance improves as compared to when the coolant is provided so that gas flows in perpendicularly with respect to each interface between the plurality of layers.

Hereinafter, exemplary embodiments, etc., will be specifically described with reference to the drawings.

Note that each of the exemplary embodiments, etc., described below shows a general or specific example. The numerical values, shapes, structural elements, the arrangement and connection of the structural elements, steps (manufacturing steps), the processing order of the steps (manufacturing steps), etc., shown in the following exemplary embodiments, etc., are mere examples, and are not intended to limit the present disclosure. Among the structural elements in the following exemplary embodiments, structural elements not recited in any one of the independent claims are described as optional structural elements.

Note that the figures are schematic diagrams and are not necessarily precise illustrations. Therefore, for example, scale reduction and the like in the figures are not necessarily the same. Furthermore, in the figures, substantially identical elements are assigned the same reference signs, and overlapping description will be omitted or simplified.

In the present specification and the drawings, the X-axis, the Y-axis, and the Z-axis represent three axes of the right-handed three-dimensional Cartesian coordinate system. In each of the exemplary embodiments, etc., the Z-axis direction is a direction of movement of the pusher, the Y-axis direction is a direction in which the conductor extends, and the X-axis direction is the width direction of the conductor. In the present specification, the phrase “as viewed from above” indicates viewing from the positive side of the Z-axis to the negative side of the Z-axis, the phrase “in a cross-sectional view” indicates viewing a cut surface of the breaker device that has been cut through by a plane extending through the Z-axis and parallel to the Z-axis, and the term “lateral/side” indicates a direction perpendicular to the Z-axis direction. Furthermore, in the present specification, the Z-axis direction is also referred to as the up-down or vertical direction. Note that the up-down or vertical direction of the breaker device in the present specification merely indicates relative positioning of elements included in the breaker device for the sake of description of each of the exemplary embodiments, etc. For example, in the present specification, the terms “up/upward/above/top” and “down/downward/below/bottom” do not indicate an upward direction (vertically upward) and a downward direction (vertically downward) in a sense of absolute space, but are used as terms defined by relative positioning on the basis of the direction of movement of the pusher. The posture of the breaker device when installed is not limited by the directions illustrated in the drawings.

Furthermore, in the present specification, terms indicating the relationship between elements such as being equal and being perpendicular, terms indicating the shapes of elements such as a circle, numerical values, and numerical ranges are not expressions referring to only exact meanings, but are expressions referring to substantially equivalent ranges including, for example, approximately a few percent (for example, approximately 10%) differences.

Furthermore, in the present specification, ordinal numbers such as “first” and “second” do not indicate the number of structural elements or the sequence of structural elements, but are used for the purpose of avoiding confusion and distinguishing between structural elements of the same kind, unless otherwise noted.

### Embodiment 1

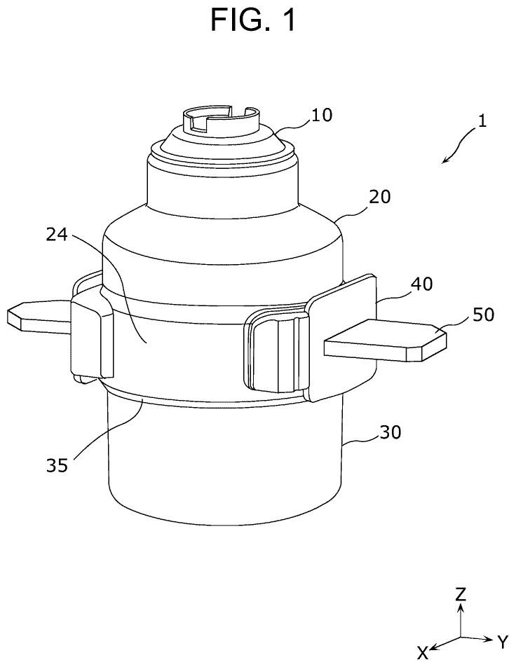

Hereinafter, the breaker device according to the present exemplary embodiment will be described with reference to FIG. 1 to FIG. 5.

### 1-1. Configuration of Breaker Device

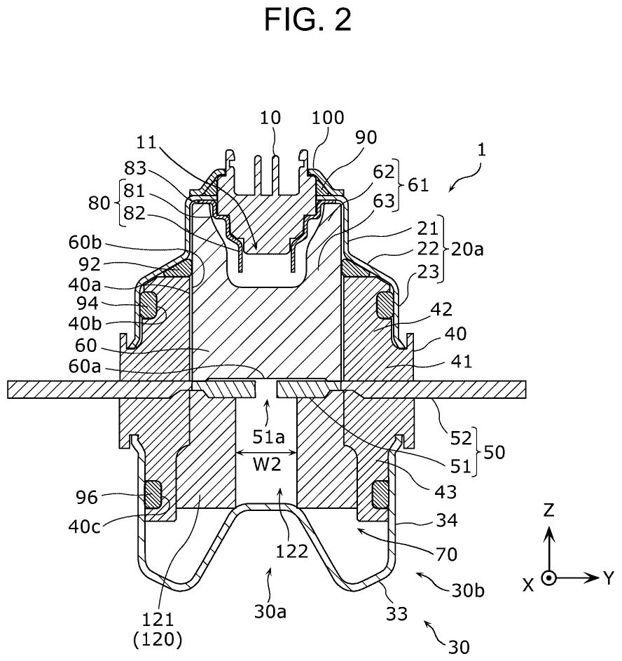

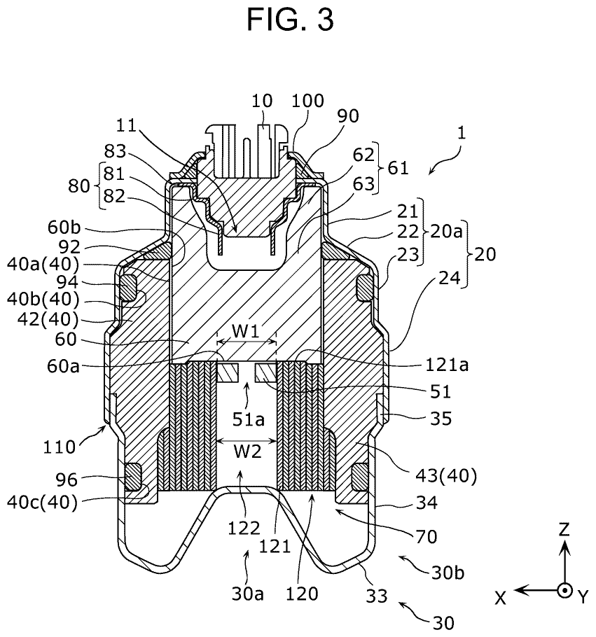

First, the configuration of the breaker device according to the present exemplary embodiment will be described with reference to FIG. 1 to FIG. 4. FIG. 1 is a perspective view illustrating breaker device 1 according to the present exemplary embodiment. FIG. 2 is a cross-sectional view of breaker device 1 according to the present exemplary embodiment cut along the YZ plane. FIG. 3 is a cross-sectional view of breaker device 1 according to the present exemplary embodiment cut along the XZ plane.

FIG. 1 illustrates breaker device 1 that has rotated around the Z-axis as an axis of rotation from the state thereof in a front view, assuming that a view projected in the X-axis direction is a front view. FIG. 2 is a cross-sectional view of breaker device 1 (in the initial state) that has not performed the interrupting operation and is cut along the YZ plane, and FIG. 3 is a cross-sectional view of breaker device 1 (in the initial state) that has not performed the interrupting operation and is cut along the XZ plane.

As illustrated in FIG. 1 to FIG. 3, breaker device 1 includes igniter 10, upper casing 20, lower casing 30, resin member 40, conductor 50, pusher 60, protective portion 80, elastic members 90, 92, 94, 96, and coolant 120. Breaker device 1 is a device that is mounted on an object including an electrical circuit and operates to interrupt the electrical circuit when an anomaly occurs in the electrical circuit, a system, or the like in the object, to thereby prevent damage caused by the anomaly from becoming severe. For example, breaker device 1 is mounted on a vehicle, which is one example of the object, and is connected between a motor and a battery (for example, a lithium-ion battery) for driving the motor to interrupt the electrical connection between the motor and the battery for driving the motor in the event of emergency situations such as malfunctions and accidents. Note that the object may be other than a vehicle; examples of the object include, but are not particularly limited to, a home appliance and a photovoltaic system.

Igniter 10 holds gunpowder inside, includes lid portion 11 between the gunpowder and pusher 60, is disposed inside recessed portion 61, and generates gas. For example, igniter 10 is an electric igniter including: a gunpowder portion including an ignition charge; and a conducting pin for passing an electric current through the gunpowder portion. During operation, an operating current for igniting the ignition charge is supplied from an external power supply to the conducting pin, thus the ignition charge is ignited and burnt, and gas (combustion gas) is generated. Note that when recessed portion 61 is formed, breaker device 1 can be reduced in size.

Igniter 10 is fixed to small-diameter portion 21 located at the top of upper casing 20.

Upper casing 20 and lower casing 30, which are members constituting the outer full of breaker device 1, house igniter 10, a portion of each of resin member 40 and conductor 50, pusher 60, protective portion 80, elastic members 92, 94, 96, and coolant 120. Space 70 extending in the up-down direction is formed inside upper casing 20 and lower casing 30. Space 70 is a space formed in the shape of a cylinder so that pusher 60 can move therein. Pusher 60 is housed in an area of space 70 that is located at the upper end (on the positive side of the Z-axis) in the up-down direction (the Z-axis direction).

Each of upper casing 20 and lower casing 30 is formed of a metal such as stainless steel (SUS), but may be formed of other metals such as aluminum. The outer shape of each of upper casing 20 and lower casing 30 is, but not limited to, a circular column. Upper casing 20 and lower casing 30 are directly connected and fixed by welding or the like, for example. Each of upper casing 20 and lower casing 30 is one example of the casing.

Upper casing 20, which is a cylinder member having the shape of a circular cylinder with a step, for example, is hollow inside. Upper casing 20 includes: small-diameter portion 21 located in an upper area; large-diameter portion 23 located in a lower area; connecting portion 22 that connects these small-diameter and large-diameter portions; and first fixing portion 24. Small-diameter portion 21, connecting portion 22, large-diameter portion 23, and first fixing portion 24 are integrally formed. Small-diameter portion 21 and large-diameter portion 23 are coaxially disposed, and large-diameter portion 23 is larger in diameter than small-diameter portion 21. Small-diameter portion 21, connecting portion 22, and large-diameter portion 23 form first body portion 20a.

First fixing portion 24, which is a part for fixing upper casing 20 and lower casing 30, is provided so as to protrude downward from first body portion 20a (for example, large-diameter portion 23).

Lower casing 30, which is a member having the shape of a hollow cylinder with a closed bottom, includes projecting portion 30a that protrudes upward. Specifically, lower casing 30 includes projecting portion 30a, bottom portion 33, side wall portion 34, and second fixing portion 35. Projecting portion 30a, bottom portion 33, side wall portion 34, and second fixing portion 35 are integrally formed. Furthermore, coolant 120 is disposed inside lower casing 30. Projecting portion 30a, bottom portion 33, and side wall portion 34 form second body portion 30b.

Note that in the present specification, being integrally formed means at least one of the following: that components are formed of the same material; that components are formed at the same time; and that components are the same object (a single object), for example.

Projecting portion 30a is located below separating portion 51 and configured so as to protrude upward in space 70. Projecting portion 30a is connected to one end of bottom portion 33 and protrudes upward (on the positive side of the Z-axis) from bottom portion 33 in space 70. Projecting portion 30a is configured so as to contact pusher 60 that has moved downward by the gas generated by igniter 10 and then deform downward by being pressed by pusher 60. This means that projecting portion 30a has the function of absorbing the impact (stress) from pusher 60 by deformation.

Projecting portion 30a, which forms the recessed portion of lower casing 30 when breaker device 1 is viewed from the negative side of the Z-axis to the positive side of the Z-axis, is exposed as viewed from the outside of breaker device 1. In the present exemplary embodiment, projecting portion 30a is tapered upward in space 70, but the shape of projecting portion 30a is not limited to this tapered shape.

Note that in the present specification, contacting means that stress can be transferred from one of two members to the other and may represent direct contact between two members or may represent that although another member is disposed between two members, the configuration is such that stress can be transferred from one of the two members to the other via the other member. For example, contact herein may represent direct contact between projecting portion 30a and separating portion 51 or may represent that the configuration is such that stress from projecting portion 30a can be transferred to separating portion 51 via another member disposed between projecting portion 30a and separating portion 51. In the latter example, for example, an arc-extinguishing material (for example, coolant 120) may be disposed between projecting portion 30a and separating portion 51 or separating portion 51 may be disposed between projecting portion 30a and pusher 60.

Bottom portion 33 connects projecting portion 30a and side wall portion 34. In other words, projecting portion 30a and side wall portion 34 are connected via bottom portion 33. Bottom portion 33 has an outer surface and an inner surface each inclined upward from projecting portion 30a to side wall portion 34.

Side wall portion 34 is connected to the other end of bottom portion 33 and is formed so as to extend upward from bottom portion 33. Side wall portion 34 has the shape of a cylinder; in the present exemplary embodiment, side wall portion 34 has the shape of a circular cylinder. Side wall portion 34 is disposed coaxially with small-diameter portion 21 and large-diameter portion 23. The diameter of side wall portion 34 is equal to the diameter of large-diameter portion 23, for example.

Second fixing portion 35, which is a part for fixing upper casing 20 and lower casing 30, is provided so as to protrude upward from second body portion 30b (for example, side wall portion 34). Second fixing portion 35 is provided at a position corresponding to first fixing portion 24 and is disposed so as to at least partially overlap first fixing portion 24 as viewed in the radial direction (in the example in FIG. 3, in the X-axis direction).

In the present exemplary embodiment, second fixing portion 35 is directly connected (joined) to first fixing portion 24; for example, second fixing portion 35 is connected to first fixing portion 24 by welding. Second fixing portion 35 is joined to first fixing portion 24 by welding portion 110. Welding portion 110 is a portion at which first fixing portion 24 and second fixing portion 35 are welded together. The welding is performed by laser welding, but may be realized in an arbitrary method such as the tungsten inert gas (TIG) welding and projection welding.

Note that second fixing portion 35 may be connected to first fixing portion 24 in a method different from welding; for example, second fixing portion 35 may be directly connected to first fixing portion 24 by soldering. Furthermore, second fixing portion 35 is not limited to being directly connected to first fixing portion 24 and may be connected to first fixing portion 24 by a fastening member such as screws.

Projecting portion 30a, bottom portion 33, side wall portion 34, and second fixing portion 35 have the same thickness in the present exemplary embodiment, but may have different thicknesses, for example.

Resin member 40 is a member that covers a part of conductor 50. Resin member 40 is a part of structural elements that form space 70. Resin member 40 includes embedding portion 41, first cylindrical portion 42, and second cylindrical portion 43.

Embedding portion 41 is a part of resin member 40 in which conductor 50 is embedded. Embedding portion 41 is partially exposed from the casing, for example.

Embedding portion 41 has a through-hole in which conductor 50 (specifically, holding portion 52) is disposed.

First cylindrical portion 42, which is a part of resin member 40 that is disposed in the casing, is where pusher 60 is disposed during a non-interrupting operation (while no gas is generated by igniter 10). This means that first cylindrical portion 42 is located between the casing and pusher 60. The inner diameter of first cylindrical portion 42 is less than the inner diameter of second cylindrical portion 43. Note that the position of pusher 60 illustrated in FIG. 2 and FIG. 3 indicates the initial position assumed during a non-interrupting operation.

Second cylindrical portion 43, which is a part of resin member 40 that is disposed in the casing, is a part located at a level below first cylindrical portion 42. The inner diameter of second cylindrical portion 43 is greater than the inner diameter of first cylindrical portion 42. Thus, the volume of the lower area of space 70 can be made large. This makes it possible to reduce an increase in the pressure inside the casing that is caused by the gas generated by igniter 10 and the following movement of pusher 60, meaning that the deformation of breaker device 1 can be minimized.

In this manner, pusher 60 moves in space 70 formed by first cylindrical portion 42 and second cylindrical portion 43. Note that first cylindrical portion 42 and second cylindrical portion 43 are not limited to having different inner diameters and may have the same inner diameter.

Furthermore, resin member 40 includes inner side wall 40a, first outer side wall 40b, and second outer side wall 40c. First outer side wall 40b and second outer side wall 40c are walls of the recesses formed in the circumferential direction on the outer side wall of resin member 40.

Inner side wall 40a, which is the inner surface of resin member 40, faces outer side wall 60b of pusher 60.

First outer side wall 40b is a part disposed in the casing, at a level above separating portion 51, and covered by upper casing 20. First outer side wall 40b is circumferentially provided so as to face large-diameter portion 23 in a cross-sectional view.

Second outer side wall 40c is a part disposed in the casing, at a level below separating portion 51, and covered by lower casing 30. Second outer side wall 40c is circumferentially provided so as to face side wall portion 34 in a cross-sectional view.

Conductor 50 is an electrically conductive metal body that is partially located in upper casing 20 and lower casing 30. When breaker device 1 is mounted on a predetermined electrical circuit, conductor 50 forms a part of said electrical circuit and is also referred to as a busbar. Conductor 50 is a flat member held on resin member 40 and disposed so as to cross the interior of each of upper casing 20 and lower casing 30. Conductor 50 includes separating portion 51 and holding portion 52.

Conductor 50 can be formed of a metal such as copper (Cu), for example. Note that conductor 50 may be formed of a metal other than copper or may be formed of an alloy of copper and another metal. For example, conductor 50 may contain manganese (Mn), nickel (Ni), platinum (Pt), or the like.

Separating portion 51, which is a part of conductor 50 to be cut off by pusher 60 under the pressure of the gas generated by igniter 10, is located below pusher 60 at the initial position. Separating portion 51 incudes hole 51a (a through-hole) extending through separating portion 51. There is one hole 51a, for example, but there may be more than one hole 51a. The shape of hole 51a as viewed from above is a circle, for example, but may be a rectangle or the like; the shape of hole 51a is not particularly limited. Note that hole 51a is not required to be formed.

Holding portion 52 is a part of conductor 50 that is held by resin member 40. Holding portion 52 is a part that does not overlap pusher 60 as viewed from above; for example, holding portion 52 is a part that overlaps resin member 40 and is a part located outside of the casing as viewed from above. Holding portion 52 remains held by resin member 40 even after separating portion 51 is cut off.

Pusher 60 is positioned below igniter 10 and disposed so as to be able to move downward and, for example, when an anomaly occurs in the system, moves downward to cut conductor 50 and interrupt the flow of an electric current through the electrical circuit as an emergency measure. Thus, pusher 60 is configured so as to cut off separating portion 51 from conductor 50 by receiving the pressure of the gas generated by igniter 10. In this manner, pusher 60 is disposed at a first position between separating portion 51 and igniter 10 (refer to FIG. 2 and FIG. 3), and cuts off separating portion 51 and moves from the first position to a second position located below the first position. The second position is, for example, the position of pusher 60 that has moved downward together with separating portion 51 until separating portion 51 comes into contact with projecting portion 30a.

Pusher 60 is formed of an insulating member such as a synthetic resin, for example. In the present exemplary embodiment, pusher 60 is formed of nylon. Pusher 60 has the shape of a circular column with an outer diameter corresponding to the inner diameter of small-diameter portion 21 of upper casing 20. Pusher 60 includes recessed portion 61, and igniter 10 is disposed inside recessed portion 61. Note that the shape of pusher 60 is not limited to said shape and can be changed, as appropriate, according to the shape, etc., of each of upper casing 20 and lower casing 30. Recessed portion 61 is an upper portion of pusher 60 where a recessed portion directed downward is provided.

In the example illustrated in FIG. 2 and FIG. 3, recessed portion 61 is a part with a lateral surface surrounded by small-diameter portion 21 and connecting portion 22 in the state where breaker device 1 has not performed the interrupting operation (the state illustrated in FIG. 2 and FIG. 3).

Recessed portion 61 includes, as viewed from above: first section 62 having a diameter (for example, an inner diameter) greater than the diameter of first cylindrical portion 81 of protective portion 80; and second section 63 located at a level below first section 62 and having a diameter (for example, an inner diameter) greater than the diameter of second cylindrical portion 82. As viewed from above, the diameter of first section 62 is greater than the diameter of second section 63. For example, in a cross-sectional view, the inner wall of first section 62 is tapered with a diameter reduced toward second section 63, but may be, for example, in the shape of a staircase with a diameter reduced stepwise.

Protective portion 80 is a structural element for protecting pusher 60 from being damaged by lid portion 11 of igniter 10 when igniter 10 generates gas. Specifically, protective portion 80 is a member serving as a barrier to a part of lid portion 11 that may open wide, to reduce the occurrence of said part opened as a result of the gas generation by igniter 10 coming into contact with pusher 60 and damaging recessed portion 61 of pusher 60.

Protective portion 80 is provided on the casing (for example, upper casing 20) or igniter 10 and includes a part located inside recessed portion 61. In the present exemplary embodiment, protective portion 80 is provided on the casing (specifically, small-diameter portion 21). Protective portion 80 is fixed to small-diameter portion 21 by welding, for example, but the fixing method is not limited to welding.

As illustrated in FIG. 2 and FIG. 3, protective portion 80 includes first cylindrical portion 81 and second cylindrical portion 82. First cylindrical portion 81 and second cylindrical portion 82 are integrally formed.

First cylindrical portion 81, which is a part in the shape of a cylinder surrounding the lateral side of igniter 10, has a shape corresponding to igniter 10. In the present exemplary embodiment, first cylindrical portion 81 is formed in the shape of a staircase (for example, in the form of a two-step staircase) with a diameter (for example, an inner diameter) reduced stepwise downward in a cross-sectional view. Note that the shape of first cylindrical portion 81 is not limited to this shape; for example, first cylindrical portion 81 may be tapered with a diameter reduced downward or may have another shape.

First cylindrical portion 81 may be at least partially in contact with igniter 10. Second cylindrical portion 82 is disposed at the lower end of first cylindrical portion 81.

First cylindrical portion 81 includes flange portion 83 at the top. Flange portion 83, which is a ring-shaped part (for example, a plate-shaped member) formed so as to protrude outward from the upper end of first cylindrical portion 81 as viewed from above, is fixed to small-diameter portion 21 by welding or the like. At least a part of flange portion 83 is disposed between first section 62 and small-diameter portion 21, for example. Thus, first cylindrical portion 81 includes a part connected to the casing and is fixed to the casing.

Second cylindrical portion 82 is a ring-shaped part located at a level below first cylindrical portion 81 and having a diameter (for example, an inner diameter) less than the diameter of first cylindrical portion 81. Second cylindrical portion 82 is a part that protrudes straight from the lower end of first cylindrical portion 81 on the negative side of the Z-axis and when the gas is generated, comes into contact with lid portion 11. The lower end (the end located on the negative side of the Z-axis, that is, the lowest end, for example) of second cylindrical portion 82 is located at a level below (on the negative side of the Z-axis from) the lower end (the end located on the negative side of the Z-axis, that is, the lowest end, for example) of lid portion 11 in the state where no gas is generated.

Protective portion 80 is formed of a metal such as stainless steel (SUS), for example, but may be formed of other metals such as aluminum or may be formed of a resin (for example, a resin different from that of pusher 60).

As illustrated in FIG. 2 and FIG. 3, elastic members 90, 92, 94, 96, which are members with elasticity such as rubber, are O-rings each formed in the shape of a ring. Each of elastic members 90, 92, 94, 96, is disposed in the state of being pressed (a deformed state).

Elastic member 90 is disposed in the space formed between small-diameter portion 21, igniter 10, and fixing member 100 for fixing igniter 10 disposed inside recessed portion 61. Elastic member 90 is in contact with each of fixing member 100, igniter 10, and small-diameter portion 21 and, for example, is pressed by each of fixing member 100, igniter 10, and small-diameter portion 21.

Elastic member 92 is provided to be positioned between the casing and pusher 60 in such a manner as to be pressed against the casing and press the outer side surface (for example, outer side wall 60b) of pusher 60. Elastic member 92 is disposed so as to extend along the outer side surface of pusher 60. In the present exemplary embodiment, elastic member 92 is disposed in the space formed between the casing (for example, connecting portion 22), pusher 60, and resin member 40 in order to keep the internal space of recessed portion 61 and the space outside of said internal space (for example, the space between pusher 60 and resin member 40) from being spatially connected. Elastic member 92 reduces the leakage of the gas generated by igniter 10 into the space outside of the internal space of recessed portion 61. With this, it is possible to minimize a reduction in the pressure of the gas inside recessed portion 61 that is due to the gas generated by igniter 10 escaping from the internal space of recessed portion 61.

In the present exemplary embodiment, elastic member 92 is in contact (for example, surface contact) with the casing, pusher 60, and resin member 40 and, for example, is pressed by each of the casing, pusher 60, and resin member 40.

The shape of a cross section of elastic member 92 when pressed is triangular, but is not limited to this shape. The shape of the cross section of elastic member 92 when not pressed is not particularly limited as long as the internal space of recessed portion 61 and conductor 50 can be spatially separated after pressing; said shape may be a circle, may be a polygon (for example, a square), or may be an ellipse.

Note that in the present specification, the term “pressing” includes, in addition to a situation in which “one member presses the other member,” a situation in which “with a repulsive force generated as a result of elastic deformation of said other member, said other member presses said one member or another member.”

Elastic member 94 is disposed in the space formed above conductor 50, between the casing (for example, large-diameter portion 23) and a circumferential recessed portion formed on resin member 40, in order to keep the exterior space and the space located above conductor 50 from being spatially connected. In the present exemplary embodiment, elastic member 94 is located between and in contact with first outer side wall 40b of resin member 40 and large-diameter portion 23 and, for example, is pressed by each of first outer side wall 40b of resin member 40 and large-diameter portion 23.

Elastic member 96 is disposed in the space formed below conductor 50, between lower casing 30 (for example, side wall portion 34) and a circumferential recessed portion formed on resin member 40, in order to keep the exterior space and the space located below conductor 50 from being spatially connected. In the present exemplary embodiment, elastic member 96 is located between and in contact with second outer side wall 40c of resin member 40 and side wall portion 34 and, for example, is pressed by each of second outer side wall 40c of resin member 40 and side wall portion 34.

Note that elastic members 94, 96 are not limited to being disposed in the circumferential recesses without spacing; spacing may be formed in at least one of the up and down directions.

Coolant 120 is preferably a layered body obtained by stacking fiber members such as glass fiber, for example. In particular, coolant 120 is preferably a layered body obtained by stacking glass wool. Specifically, coolant 120 includes a plurality of layers 121, and an interface is formed at the boundary between the plurality of layers 121. Note that in FIG. 3, layers 121 are illustrated so that adjacent layers 121 have different hatching patterns. The number of layers of coolant 120 is not particularly limited.

As illustrated in FIG. 3, the plurality of layers 121 are stacked in the X-axis direction, and end surface 121a of each of the plurality of layers 121 is disposed facing lower surface 60a of pusher 60. Note that end surface 121a forms an end surface (upper end surface) of coolant 120 that is located in a direction (in the example in FIG. 3, the positive Z-axis direction) perpendicular to a direction in which layers 121 are stacked (in the example in FIG. 3, the X-axis direction).

Coolant 120 including the plurality of layers 121 is less likely to allow passage of gas flowing in the direction in which layers 121 are stacked (in the example in FIG. 3, the X-axis direction) and is more likely to allow passage of gas flowing in a direction (in the example in FIG. 3, the Z-axis direction and the Y-axis direction) perpendicular to the direction in which layers 121 are stacked.

Furthermore, in breaker device 1, gas flows mainly from top to bottom (from the first position to the second position) during an interrupting operation. Therefore, when coolant 120 is disposed as illustrated in FIG. 3, high-temperature gas generated during an interrupting operation and flowing downward easily passes through the inside of coolant 120. Thus, the temperature of the gas can be effectively reduced and therefore, it is possible to improve the cooling effect of coolant 120.

Coolant 120 is disposed at a level below pusher 60; in the initial state, coolant 120 is compressed and disposed in space 70 and is in contact with projecting portion 30a, resin member 40, conductor 50, and pusher 60. Furthermore, coolant 120 includes a recessed portion or through-hole 122.

Coolant 120 is configured to, when coming into contact with an electric arc or gas generated upon ignition, absorb the heat of the electric arc or the gas to cool the electric arc or the gas. This reduces the increase in pressure in space 70 that is due to the generation of an electric arc. The gas mentioned is gas that has a high temperature due to the generation of the electric arc. Furthermore, the gas may include the gas generated by igniter 10.

Note that coolant 120 is not limited to being in the form of fiber such as glass fiber and may be in the form of particles. For example, coolant 120 may include a large number of particles. The particles may be a metal oxide such as alumina particles or may be an inorganic oxide such as silica, for example.

Although the foregoing describes an example in which coolant 120 is disposed at a level above an area around the upper surface of projecting portion 30a, at least a part of coolant 120 may be disposed at a level below an area around the upper surface of projecting portion 30a. For example, coolant 120 may be disposed at a level below an area around the upper surface of projecting portion 30a, in at least a part of an annular space formed by projecting portion 30a, bottom portion 33, and side wall portion 34.

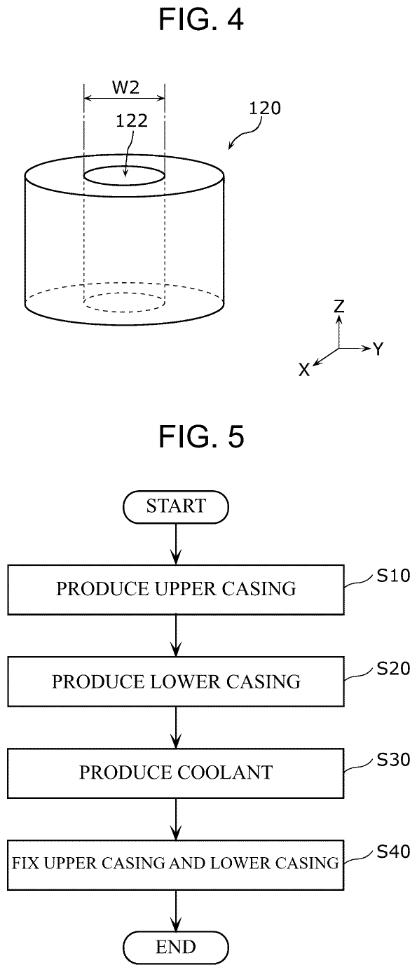

Next, the configuration of coolant 120 will be described further with reference to FIG. 4. FIG. 4 is a perspective view illustrating coolant 120 according to the present exemplary embodiment. Note that in FIG. 4, the illustration of the boundaries of layers 121 is omitted for the sake of convenience.

As illustrated in FIG. 3 and FIG. 4, through-hole 122 is provided in coolant 120 in the present exemplary embodiment. Through-hole 122 extends through coolant 120 from the upper surface of coolant 120 to the lower surface of coolant 120 (from the positive side of the Z-axis to the negative side of the Z-axis). The shape of through-hole 122 is a circular column, for example, but is not particularly limited.

Through-hole 122 is provided at a position overlapping hole 51 a of separating portion 51 as viewed from above. Through-hole 122 is formed concentrically with hole 51a of separating portion 51 and has a diameter greater than the diameter of said hole 51a, as viewed from above, for example. Coolant 120 is located at a level below separating portion 51, and width W2 of the opening of through-hole 122 is greater than width W1 of separating portion 51. It is sufficient that through-hole 122 and hole 51 a at least partially overlap each other as viewed from above.

Note that through-hole 122 is a part of space 70. Width W1 is the length of separating portion 51 along the X-axis. Furthermore, width W1 is the dimension of coolant 120 compressed by projecting portion 30a, resin member 40, conductor 50, and pusher 60.

With such coolant 120, it is possible to increase the surface area of the coolant that comes into contact with the gas as compared to when through-hole 122 is not formed. As a result, the heat of the electric arc or the gas can be further absorbed, meaning that the electric arc or the gas can be further cooled. Thus, when through-hole 122 is provided in coolant 120, it is possible to improve the cooling performance while reducing the increase in the size of breaker device 1 and the increase in the number of components of breaker device 1.

Furthermore, when the breaker device includes a resin member (for example, resin member 40), carbonized gas may be generated from the resin member during an interrupting operation. The carbonized gas adheres to a surface of the coolant. As a result, the area of contact between the electric arc or the gas and the coolant is reduced and therefore, the cooling performance of the coolant degrades. In contrast, in the present exemplary embodiment, coolant 120 includes through-hole 122 and has a large surface area, meaning that the impact the carbonized gas has on the cooling performance can be mitigated. Furthermore, since the electric arc or the internal gas passes through the inside of coolant 120, the inside of coolant 120 can be effectively used. As a result, coolant 120 according to the present exemplary embodiment can improve the cooling performance as compared to a conventional technique.

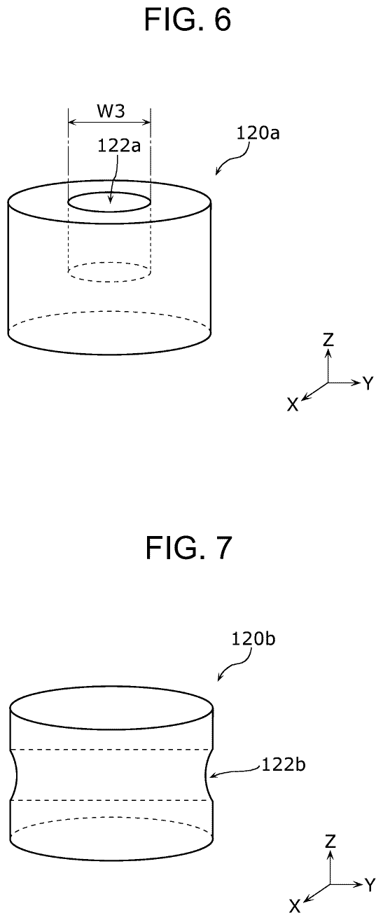

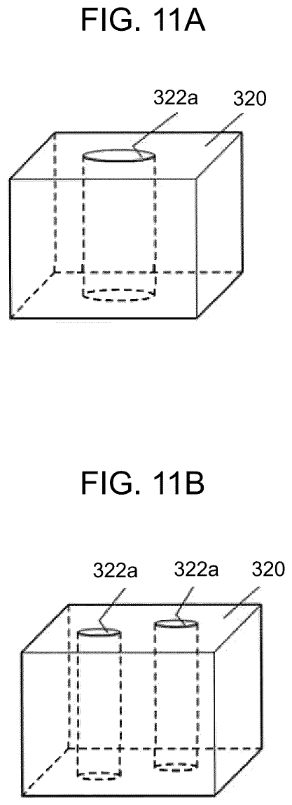

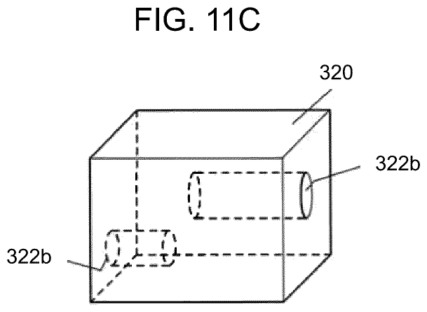

Note that the outer shape of coolant 120 illustrated in FIG. 4 and FIG. 6 is a circular column, but the outer shape of coolant 320 may be a quadrangular prism, as illustrated in FIG. 11A to FIG. 11C. The outer shape of coolant 320 may be other pillar shapes such as a triangular prism, a hexagonal prism, and an elliptical cylinder. Even when the outer shape of coolant 320 is different from a circular column, through-hole 322a and recessed portion 322b are formed in coolant 320, as in the exemplary embodiment described above.

Note that a plurality of through-holes 322a and a plurality of recessed portions 322b may be formed in coolant 320. A direction in which each of through-holes 322a and recessed portion portions 322b extends does not need to the left-right direction or the up-down direction and may be an oblique direction.

### 1-2. Method for Manufacturing Breaker Device

Next, the method for manufacturing breaker device 1 configured as described above will be described with reference to FIG. 5. FIG. 5 is a flowchart illustrating a manufacturing process of breaker device 1 according to the present exemplary embodiment.

As illustrated in FIG. 5, upper casing 20 is produced by molding or the like (S10), and lower casing 30 is produced by molding or the like (S20). In Step S10, protective portion 80 is further provided on upper casing 20. For example, protective portion 80 is fixed to upper casing 20 by welding or the like. Furthermore, in Step S20, projecting portion 30a is formed at the same time as lower casing 30 is produced by molding.

Next, coolant 120 is produced from an original sheet for coolants (S30). The original sheet is a large sheet that is a layered body obtained by stacking the plurality of layers 121. In the original sheet, the plurality of layers 121 are stacked in the thickness direction.

In Step S30, the original sheet is cut into pieces each in the shape of a rectangle or the like, for example, a cut surface (side surface) of the original sheet on which the plurality of layers are stacked is cut with a die corresponding to through-hole 122, and thus through-hole 122 is formed.

Note that the order of Steps S10, S20, S30 is not limited to this order and may be changed.

Next, upper casing 20 and lower casing 30 are fixed (S40). For example, upper casing 20 and lower casing 30 are fixed by welding or the like in the state where igniter 10, resin member 40, conductor 50, pusher 60, protective portion 80, elastic members 90, 92, 94, 96, and coolant 120 are housed in the casings. At this time, coolant 120 is disposed in space 70 in the state where coolant 120 is in contact with and compressed by projecting portion 30a, resin member 40, conductor 50, and pusher 60. As a result, breaker device 1 described above is produced

### Various Variations of Embodiment 1

The above exemplary embodiment describes, with reference to FIG. 4, the coolant in which the through-hole is formed in the up-down direction, but the coolant is not limited to having the shape illustrated in FIG. 4. Hereinafter, various variations of the coolant will be described with reference to FIG. 6 to FIG. 9. FIG. 6 to FIG. 9 are perspective views illustrating coolants according to various variations of Embodiment 1. A breaker device according to a variation may include a coolant according to one of the various variations instead of coolant 120 according to Embodiment 1.

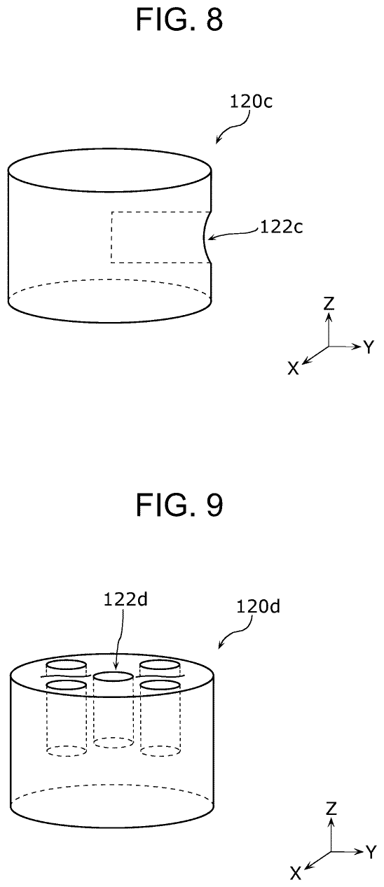

Note that FIG. 6 to FIG. 9 are perspective views each illustrating a coolant disposed inside the casing. In FIG. 6 to FIG. 9, the illustration of the plurality of layers 121 is omitted. The depth and shape of the recessed portion illustrated in each of FIG. 6, FIG. 8, and FIG. 9 and the shape of the through-hole illustrated in FIG. 7 are not particularly limited as long as gas can flow into the recessed portion and the through-hole.

As illustrated in FIG. 6, the breaker device may include coolant 120a in which recessed portion 122a is provided. Recessed portion 122a is open upward (on the positive side of the Z-axis) and is provided facing lower surface 60a of pusher 60. Width W3 of the opening of recessed portion 122a is greater than width W1 of separating portion 51, for example.

Furthermore, as illustrated in FIG. 7, the breaker device may include coolant 120b having a side surface through which through-hole 122b extends. Through-hole 122b is provided in a direction perpendicular to the direction of movement of pusher 60 (the up-down direction).

Furthermore, as illustrated in FIG. 8, the breaker device may include coolant 120c having a side surface in which recessed portion 122c is provided. Recessed portion 122c is provided so as to be open laterally (in a direction perpendicular to the Z-axis).

As illustrated in FIG. 9, the breaker device may include coolant 120d having an upper surface in which a plurality of recessed portions 122d are provided. Recessed portion 122d is one of the plurality of recessed portions 122d.

Note that FIG. 9 illustrates an example in which coolant 120d includes five recessed portions 122d, but the number of recessed portions 122d in coolant 120d is not limited to five; it is sufficient that coolant 120d include two or more recessed portions 122d. The shapes (for example, the shapes viewed from above) and depths of the plurality of recessed portions 122d may be the same or different. The plurality of recessed portions 122d may be provided in the side surface of coolant 120d.

Note that coolant 120d may include a plurality of through-holes instead of the plurality of recessed portions 122d. The through-hole is one of the plurality of through-holes.

Even when the coolants according to various variations are used as described above, it is possible to increase the surface area of the coolant as compared to when no recessed portions or through-holes are formed, meaning that it is possible to realize a breaker device in which the cooling performance can be improved as compared to a conventional technique.

### Embodiment 2

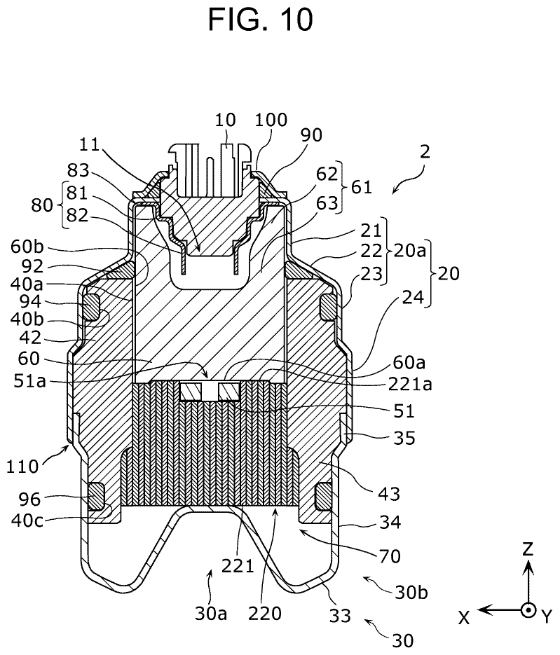

Hereinafter, a breaker device according to the present exemplary embodiment will be described with reference to FIG. 10. Note that the following description will focus on differences from Embodiment 1, and description of details that are the same as or similar to those described in Embodiment 1 will be omitted or simplified.

FIG. 10 is a cross-sectional view of breaker device 2 according to the present exemplary embodiment cut along the XZ plane.

As illustrated in FIG. 10, breaker device 2 according to the present exemplary embodiment includes coolant 220 instead of coolant 120 included in breaker device 1 according to Embodiment 1. Coolant 220 is different from the coolants described in Embodiment 1 and variations thereof mainly in that no recessed portions or through-holes are formed.

In the coolant 220, a plurality of layers 221 are stacked in the X-axis direction, and coolant 220 is disposed so that end surface 221a of each of the plurality of layers 221 faces lower surface 60a of pusher 60. Coolant 220 is also provided at a position overlapping separating portion 51 as viewed from above. Coolant 220 is also provided at a position overlapping separating portion 51 and hole 51a as viewed from above. For example, coolant 220 is provided at a position overlapping pusher 60 as viewed from above. Note that the material of layers 221 is substantially the same as that in Embodiment 1.

Coolant 220 is provided so as to fill, without spacing, a space located above the upper surface of projecting portion 30a and below lower surface 60a of pusher 60 or the lower surface of separating portion 51. In other words, coolant member 220 does not include recessed portions or through-holes. The phrase “not include” means that no recessed portions or through-holes are provided intentionally in producing coolant 220; for example, said phrase does not include a situation in which another member forms a recess in the state where the coolant is compressed and disposed inside the casing.

In this manner, when the direction in which the plurality of layers 221 are stacked is perpendicular to the direction of movement of pusher 60, that is, when the boundary between adjacent layers included in the plurality of layers 221 is parallel to the direction of movement of pusher 60, it is possible to improve the cooling performance of coolant 220 without forming the recessed portion or the through-hole in the coolant.

### Other Exemplary Embodiments

The breaker devices according to one or more aspects have been described thus far based on the exemplary embodiments, etc., but the present disclosure is not limited to these exemplary embodiments, etc. Various modifications to the present exemplary embodiments and forms configured by combining structural elements in different exemplary embodiments that can be conceived by those skilled in the art may be included within the present disclosure as long as these do not depart from the essence of the present disclosure.

For example, the above exemplary embodiments, etc., describe examples in which the casing is made from a metal, but this is not limiting; for example, the lower casing included in the casing may be made from a resin with deformation properties.

Furthermore, in the above exemplary embodiments, the recessed portion or the through-hole is provided so as to extend in a straight line, but the shape thereof is not limited to a straight line and may be wavy, the shape of the letter “L”, or the like.

The order of the steps in the method for manufacturing the breaker device described in the above exemplary embodiments, etc., may be changed. Furthermore, the steps in the method for manufacturing the breaker device described in the above exemplary embodiments may be performed in a single step or may be performed in separate steps. Note that the phrase “the steps are performed in a single step” is intended to include a situation in which the steps are performed using a single device, a situation in which the steps are sequentially performed, and a situation in which the steps are performed at the same location. The term “separate steps” is intended to include a situation in which the steps are performed using separate devices, a situation in which the steps are performed at different times (for example, on different dates), and a situation in which the steps are performed at different locations.

### INDUSTRIAL APPLICABILITY

The Present Disclosure Is Useful in Breaker Devices That Are Disposed in an electrical circuit, etc.

### REFERENCE SIGNS LIST

1,2 breaker device
10 igniter
11 lid portion
20 upper casing
20a first body portion
21 small-diameter portion
22 connecting portion
23 large-diameter portion
24 first fixing portion
30 lower casing
30a projecting portion
30b second body portion
33 bottom portion
34 side wall portion
35 second fixing portion
40 resin member
40a inner side wall
40b first outer side wall
40c second outer side wall
41 embedding portion
42, 81 first cylindrical portion
43,82 second cylindrical portion
50 conductor
51 separating portion
51a hole
52 holding portion
60 pusher
60a lower surface
60b outer side wall
61 recessed portion
62 first section
63 second section
70 space
80 protective portion
83 flange portion
90, 92, 94, 96 elastic member
100 fixing member
110 welding portion
120, 120a, 120b, 120c, 120d, 220, 320 coolant
121, 221 layer
121a, 221a end surface
122, 122b, 322a through-hole
122a, 122c, 122d, 322b recessed portion
W1, W2, W3 width

1. A breaker device comprising:
a casing;
an igniter disposed in the casing;
a conductor including a separating portion disposed below the igniter;
a pusher disposed at a first position between the separating portion and the igniter and configured to cut off the separating portion and move from the first position to a second position located below the first position; and
a coolant disposed at a level below the pusher and including a recessed portion or a through-hole.

2. The breaker device according to claim 1, wherein
the coolant includes a plurality of recessed portions or a plurality of through-holes,
the recessed portion is one of the plurality of recessed portions, and
the through-hole is one of the plurality of through-holes.

3. The breaker device according to claim 1, wherein
the separating portion includes a hole extending through the separating portion, and
the recessed portion in the coolant or the through-hole in the coolant overlaps the hole of the separating portion as viewed from above.

4. The breaker device according to claim 1, wherein
the coolant includes the recessed portion, and
the recessed portion is open upward and faces a lower surface of the pusher.

5. The breaker device according to claim 1, wherein
the coolant includes the through-hole, and
the through-hole extends through the coolant from an upper surface of the coolant to a lower surface of the coolant.

6. The breaker device according to claim 1, wherein
the coolant is located at a level below the separating portion, and
a width of an opening of the recessed portion or a width of an opening of the through-hole is greater than a width of the separating portion.

7. The breaker device according to claim 1, wherein
the coolant includes a plurality of layers stacked on top of each other, and an end surface of each of the plurality of layers is disposed facing a lower surface of the pusher.

8. The breaker device according to claim 1, wherein
the recessed portion in the coolant is provided in a side surface of the coolant, or the through-hole extends through the side surface of the coolant.

9. A breaker device comprising:
a casing;
an igniter disposed in the casing;
a conductor including a separating portion disposed below the igniter;
a pusher disposed at a first position between the separating portion and the igniter and configured to cut off the separating portion and move from the first position to a second position located below the first position; and
a coolant disposed at a level below the pusher, wherein
the coolant includes a plurality of layers stacked on top of each other, and an end surface of each of the plurality of layers is disposed facing a lower surface of the pusher.

10. The breaker device according to claim 1, wherein
the coolant is a fiber member.

11. The breaker device according to claim 10, wherein
the fiber member is glass fiber.

12. The breaker device according to claim 1, wherein an outer shape of the coolant is a circular column.

13. The breaker device according to claim 1, wherein
an outer shape of the coolant is a polygonal prism.
